(19) United States
(12) Patent Application Publication
(10) Pub. No.: US 2025/0095966 A1
(43) Pub. Date: Mar. 20, 2025

(54) PLASMA-ENHANCED CHEMICAL VAPOUR DEPOSITION APPARATUS

(71) Applicant: LEYDENJAR TECHNOLOGEIS B.V., Leiden (NL)

(72) Inventors: Pavel KUDLACEK, Leiden (NL); Arjen DIDDEN, Leiden (NL)

(21) Appl. No.: 18/725,893

(22) PCT Filed: Dec. 29, 2022
(86) PCT No.: PCT/NL2022/050766

§ 371 Date: Jul. 1, 2024

(30) Foreign Application Priority Data
Dec. 30, 2021 (NL) 2030360

(51) Int. Cl. H01J 37/32

(52) U.S. Cl. CPC H01J 37/3222; H01J 37/32229; H01J 37/32513; H01J 37/32807; H01J 37/3288

(57) ABSTRACT

The present invention relates to an apparatus (10) for plasma enhanced chemical vapour deposition, comprising: a reaction chamber (11); and at least one linear plasma source assembly (12) comprising (i) at least one linear antenna (13) and (ii) at least one coaxial dielectric tube (14) positioned around the linear antenna; and at least one radiofrequency generator (15); wherein the reaction chamber (11) is configured with at least one movable wall (16), the wall being configured to be movable between a first operational location (A) and a second non-operational location (B); and the at least one linear plasma source assembly (12) and at least one radiofrequency generator (15) are attached to at least one movable wall (16) and are configured to allow the at least one radiofrequency generator (15) to deliver radio wave radiation to the at least one linear plasma source assembly (12).

This invention relates to a plasma-enhanced chemical vapour deposition apparatus that advantageously allows for rapid cleaning and/or replacement of constituent internal components.

### BACKGROUND

Plasma-enhanced chemical vapour deposition (PECVD) is widely employed in high volume coating of substrates with thin layers of deposited material. PECVD is used to deposit thing films from a gaseous vapour state onto substrates where it forms a solid state. The deposition process involves chemical reactions which occur after introductions of the feedstock gasses to the plasma. The plasma is typically generated by radio frequency (RF) or direct current (DC) discharge between two electrodes, with the space between the electrodes comprising the reacting gasses.

The deposition of thin-film coatings is used in various applications, such as electronics (battery materials, microchips, etc), corrosion-resistant and tribological coatings such as refractory films (titanium or aluminium nitrides, carbides and oxides), coatings having beneficial optical properties (anti-reflection, Solar-protection, filter, etc.), coatings providing other biological or physiochemical properties (antimicrobial, self-cleaning, hydrophilic, hydrophobic, oxygen impermeable packaging layer etc.), and conductive films for various applications (photovoltaics, LEDs, OLEDs, organic photovoltaics, etc.).

Typical substrates comprise glass, steel, copper foils, ceramics, organic polymers, thermoplastics, etc.

For most industrial applications deposition of a film of homogeneous thickness onto a substrate is desirable, especially for continuous processes. One approach employed in the art is the use of PECVD with linear plasma sources. These linear plasma sources typically comprise a rod-shaped antenna, which is arranged within a co-axial dielectric tube. This combination of rod-shaped antenna and dielectric tube is often referred to as the inner conductor of a coaxial conductor assembly. The outer conductor of is then formed using use by plasma generated on the outside dielectric tube. This coaxial conductor arrangement forms the actual plasma source. In some cases, the linear plasma source is surrounded by a baffle assembly, or wall with an opening, through which the plasma emerges in the direction of a substrate to be coated. Such baffles and/or walls allow for control of the direction of the plasma. In such systems, the plasma source extends along an axis that extends along the axis of the rod-shaped antenna with a defined length, thereby providing a linear plasma source that is substantially uniform along the length of the linear plasma source. Examples of such sources can be found in DE 19812558 B4.

US 2009/238998 A1 concerns systems for achieving improved film properties by introducing additional processing parameters, such as a movable position for the microwave source and pulsing power to the microwave source, and extending the operational ranges and processing windows with the assistance of the microwave source. The purpose of the moving antenna in this patent is as a means of process control for a chemical sputtering system, not to allow for rapid removal of parasitically deposed material from internal components that minimizes accidental deposition of material within the reaction chamber.

WO 94/11544 A1 concerns a method and apparatus for the simultaneous plasma assisted chemical vapor deposition of thin film material onto an elongated web of substrate material at a plurality of discrete spatially separated deposition zones. The web of substrate that can be treated by the specific embodiment of FIGS. 1 and 2 must be transparent for microwaves. The apparatus of this patent suffers from a specific inherent design problem. That is, the prior art apparatus, due to its specific configuration, does not allow for rapid removal of parasitically deposed material from internal components that minimizes accidental deposition of material within the reaction chamber.

During typical PECVD processes using linear plasma sources, a first gas, which contains little to no chemically active precursor materials of the process, is introduced into the plasma source near the antenna, while a second gas, which contains most or all of chemically active deposition material of the process, is typically introduced into the plasma source near a substrate surface of the to be treated substrate.

PECVD processes utilising PECVD apparatuses with linear plasma sources may be advantageously used to provide substrates coated with a uniform coating of deposed material. However, serious issues arise from the phenomenon known as parasitic deposition. Parasitic deposition is where the material intended to be deposited upon the substrate is actually deposited on components of the PECVD apparatus. This parasitic deposition is minimized to try to maximise energy and atom efficiency, but is virtually never entirely precluded. The accumulation of parasitically deposed material tends to continue until such a point that the parasitically deposed material detaches from the PECVD apparatus, for instance by flaking off the linear plasma source or the baffles around it. Such material may fall directly onto the substrate intended to be coated, the substrate while it is being coated or onto the coated substrate, all of which lower the quality of the coating. Such material need not fall directly onto the substrate, but may be entrained by gas flow during the coating process.

To avoid damage to the quality of the coated substrate, the parasitically deposed material is typically removed by cleaning of the PECVD apparatus and/or components thereof. This is economically disadvantageous in terms of plant efficiency and cost in employee time, but is necessary to ensure the quality of the coated substrates.

A disadvantage of most PECVD apparatuses is that such cleaning of internal components typically requires either (i) cleaning of the components within the reaction chamber or (ii) partial (or complete) disassembly of the apparatus so that components can be cleaned separately. The main disadvantage of (i) cleaning the components in situ is that during removal of the parasitically deposed material, material is often accidentally detached from the component and introduced to another hard-to-access part of the apparatus. The accidentally detached material is often subsequently deposited onto a substrate during the next deposition run, leading to lower quality coating. The main disadvantages of (ii) partial disassembly of the apparatus so that components can be cleaned separately are the down-time imposed on the line and that during partial disassembly material is often accidentally detached from the component(s) being removed. Such accidentally detached material is often introduced to another hard-to-access part of the apparatus. The accidentally detached material is often subsequently deposited onto a substrate during the next deposition run, leading to lower quality coating.

An outstanding challenge is therefore the provision of an apparatus for plasma enhanced chemical vapour deposition that allows for rapid removal of parasitically deposed material from internal components that minimizes accidental deposition of material within the reaction chamber.

### BRIEF SUMMARY OF THE DISCLOSURE

In accordance with the present inventions there is provided an apparatus for plasma enhanced chemical vapour deposition, a method for depositing coatings onto a substrate, a method for cleaning said apparatus, the use of an apparatus according to any embodiment of the first aspect of the invention.

### BRIEF DESCRIPTION OF THE DRAWINGS

Embodiments of the invention are further described hereinafter with reference to the accompanying drawings, in which:

FIG. 1 depicts a top-down cross-sectional view of an apparatus according to the first aspect of the invention with the moveable wall in a first operational position.

FIG. 2 depicts a top-down cross-sectional view of the same apparatus as depicted in FIG. 1 with the moveable wall in a second non-operational position.

FIG. 3 depicts a top-down cross-sectional view of the same apparatus as depicted in FIGS. 1 and 2, depicting accidental detachment of parasitically deposited material on detachment of coaxial dielectric tube (14), which does not result in accidental deposition of the of parasitically deposited material within the reaction chamber.

FIG. 4 depicts a top-down cross-sectional view of the an embodiment of the apparatus according to the first aspect of the invention, with parasitic deposition shielding elements (18), gas supply means (19) and gas exhaust means (21). The moveable wall is in a second non-operational position.

FIG. 5 depicts a top-down cross-sectional view of the same embodiment of the apparatus as depicted in FIG. 4. The moveable wall is in a first operational position.

FIG. 6 depicts a top-down cross-sectional view of an apparatus according to an embodiment of the first aspect of the invention comprising internal frame element (23). The moveable wall (16) is in a first operational position.

FIG. 7 depicts a top-down cross-sectional view of the same apparatus as depicted in FIG. 6. moveable wall (16) is in a second non-operational position. The internal frame element (23) has been reversibly detached from the moveable wall (16).

FIG. 8 depicts a top-down cross-sectional view of an apparatus according to an embodiment of the first aspect of the invention, comprising a radio wave waveguide (17).

### DETAILED DESCRIPTION

In a first aspect, the invention concerns a plasma source assembly suitable for plasma enhanced chemical vapour deposition (PECVD).

Within the context of the present invention, the following definitions will be used:
Axial symmetry: Axial symmetry is symmetry around an axis; an object is axially symmetric if its appearance is unchanged if rotated around an axis. For example, a baseball bat without trademark or other design, or a plain white tea saucer, looks the same if it is rotated by any angle about the line passing lengthwise through its centre, so it is axially symmetric. Axial symmetry can also be discrete with a fixed angle of rotation, 360°/n for n-fold symmetry. The principle axis of rotational symmetry of an element is the axis around which the highest degree of rotational symmetry is possessed by that object.

Axial symmetry can also be discrete with a fixed angle of rotation, 360°/n for n-fold symmetry.
Radio Frequency: Radio frequency (RF) is the oscillation rate of an alternating electric current or voltage or of a magnetic, electric or electromagnetic field in the frequency range from 20 KHz to 300 GHz.
Microwave: Microwave (MW) is the oscillation rate of an alternating electric current or voltage or of a magnetic, electric or electromagnetic field in the frequency range from 300 MHZ and 300 GHz respectively.
a microwave absorbing substrate is one which absorbs at least 5% of incident radiation at a wavelength of in the frequency range from 300 MHz and 300 GHz. respectively.

In a first embodiment, the invention concerns an apparatus for plasma enhanced chemical vapour deposition, comprising:
a reaction chamber; and
at least one linear plasma source assembly comprising (i) at least one linear antenna and (ii) at least one coaxial dielectric tube positioned around the linear antenna; and
at least one radiofrequency generator;
   wherein:
the reaction chamber is configured with at least one movable wall, the wall being configured to be movable between a first operational location and a second non-operational location; and
the at least one linear plasma source assembly and at least one radiofrequency generator are attached to at least one movable wall and are configured to allow the at least one radiofrequency generator to deliver radio wave radiation to the at least one linear plasma source assembly.

The apparatus according to the first aspect of the invention advantageously allows parasitically deposited material to be removed from components of the apparatus without accidental deposition of parasitic material within the reaction chamber. Such accidentally deposed material leads to lower quality deposition during subsequent deposition processes, as the accidentally deposed material ends up being transported to the substrate during the subsequent deposition processes leading to non-uniform deposition onto the substrate. As such, the apparatus allows for higher quality substrates to be obtained due to less accidental deposition of parasitic material.

The reaction chamber is configured to allow plasma enhanced chemical vapour deposition. The reaction chamber may optionally be configured to allow operation at reduced pressures (partial vacuum). Preferably, the reaction chamber is configured to allow operation at pressures of from 1 to 120,000 Pa, more preferably of from 100 to 110,000 Pa, even more preferably of from 1,000 to 105,000 Pa, most preferably of from 10,000 to 102,000 Pa.

The at least one linear plasma source is configured to allow the generation of plasma.

Preferably, the linear antennas have a length equal to the width of the reaction chamber. Suitable linear antennas include solid and hollow cylinders with a radius of from 1 to 20 mm, more preferably 5-10 mm, most preferably 7-9 mm. Suitable linear antennas are made from conductive material, preferably metal, more preferably copper.

Suitable coaxial dielectric tubes may be made of material that are largely transparent to microwaves and have sufficient mechanical strength to survive the pressure differences between atmospheric pressure and the operating vacuum across the tube and thermal stability to the operating temperature of the plasma. Preferable, the coaxial dielectric tubes are made of fused silica, ceramic tubes, alumina or quartz. Preferably, the coaxial dielectric tubes have a length of from 600 to 3500 mm, more preferably of from 1200 to 3000 mm, yet more preferably of from 1500 to 2500 mm and most preferably of from 1800 to 2200 mm. Preferably, the coaxial dielectric tubes have a diameter of from 60 to 20 mm, more preferably of from 50 to 30 mm, yet more preferably of from 45 to 35 mm and most preferably of from 38 to 42 mm. Coaxial is defined with respect to the axis of the antenna.

The linear plasma assembly is configured so that the radio frequency generator can deliver radio wave radiation to a first distal end of the linear (radio wave) antenna. In a preferred embodiment, radio frequency generator may be placed in direct contact with the linear antenna or the radio frequency generator may transmit radio frequency waves to the linear antenna via a wave-splitter. Transmitting radio frequency waves to the linear antenna via a wave-splitter advantageously allows for lower energy consumption per linear antenna.

The linear plasma assembly is preferably configured so that the radio frequency generator can deliver radio wave radiation to a second distal end of the linear (radio wave) antenna via a radio wave waveguide.

The linear plasma assembly(ies) and radio wave generator(s) are configured so that the radio wave generator(s) can send, and the antenna(s) receive, radio wave radiation of the same wavelength.

This configuration advantageously allows radio waves to be simultaneously provided to both distal portions of the linear antenna by only one microwave source. This results in the thermal energy provided by the antenna to the plasma being substantially uniform along the length of the antenna, which in turn advantageously results in a uniform plasma along the length of the linear plasma source and allows for depositing thin layers onto a substrate uniformly.

This configuration of elements advantageously allows for the provision of PECVD apparatus in which all the radio wave sources are located on one side of the apparatus, with respect to the direction of substrate movement through the PECVD apparatus. This reduces the structural complexity of the apparatus as a whole and allows for more compact apparatus with a footprint. This specific configuration also advantageously allows the one or more waveguides to be located closer to the one or more linear plasma sources than in conventional systems. This is because a specific disadvantage of locating a waveguide close to the plasma source in a PECVD apparatus in conventional, known systems is the more rapid accumulation of parasitic deposits on the waveguide itself, or shielding configured around the waveguide, which in turn reduces the continuous run time of such an apparatus. With the present configuration, the waveguide may be readily cleaned, obviating the line-down time associated with a more proximal waveguide. This in turn allows a more compact construction, which allows more linear plasma sources to be placed close to a substrate over the same length of the substrate, which may advantageously allow for less thermal tempering between depositions.

Suitable radio frequency generators include magnetrons, solid-state microwave generators.

Preferably, the reaction chamber (11), at least one linear plasma source assembly (12) and at least one radiofrequency generator (15) and any other element are configured to provide an apparatus suitable for plasma enhanced chemical vapour deposition onto a microwave absorbing substrate. Such a configuration necessitates that elements are configured to allow the radiation generated by the one or more radiofrequency generators (15) to be provided to the one or more linear plasma source assemblies (12) without the radiation transiting through the microwave absorbing substrate. By way of non-limiting example, a microwave absorbing substrate may be a metallic foil, such as a copper foil or a nickel foil. This specific configuration advantageously allows for PECVD onto metallic foils. The reaction chamber is configured with at least one movable wall. This moveable wall is configured to be movable between a first operational location and a second non-operational location. The first operational location is such that the wall closes off the reaction chamber so as to allow PECVD within the reaction chamber. The second non-operational location is preferably one in which no part of the linear plasma source(s) attached to the moveable wall resides within a volume defined by the reaction chamber. This advantageously allows for parasitically deposited material to be removed from the plasma source(s) attached to the moveable wall without accidental deposition of parasitically deposited material from the linear plasma source(s) to the reaction chamber.

By way of non-limiting example, the movable wall may be configured to move using hinges, rollers, wheels, rails and/or rollers on rails, more preferably rollers on rails. Preferably, the movable wall is configured to move using hinges, rails and/or rollers on rails, more preferably using rails and/or rollers on rails. This preferable embodiment allows the movable wall to be moved between a first operational location and a second non-operable location with minimal degrees of freedom in the movement. This advantageously minimizes: (i) vibrations; (ii) shocks; and (iii) the likelihood of accidental collisions of elements attached to the movable wall (16) or the movable wall (16) itself, during moving the movable wall (16) between a first operational location (A) and a second non-operational location (B). The result of using these specific movement means is that less likely that parasitically deposed material is accidentally deposited in the apparatus and/or substrate during the cleaning operation. This specific combination of features also advantageous allows for easier and more reliable vacuum seals to be formed.

More preferably, the movable walls are configured to be slidably moveable between a first operational location and a second non-operational location. This confers the advantage that the apparatus can be quickly and easily moved between the two positions, minimizing line down time between deposition runs. Additionally, due to being slidably moveable, vibration of the moveable wall and components attached thereto is minimized. This advantageously minimizes or entirely precludes accidental deposition of parasitically deposed material from the moveable wall and components attached thereto to the reaction chamber during moving the movable wall.

One optional way to remove the parasitically deposited material from the linear plasma source(s) is physical abrasion of the parasitically deposited material, which may result in particles of parasitically deposited material falling under the influence of gravity. Unlike known ways of removing parasitically deposited material from linear plasma source(s) in which part of the linear plasma source(s) reside within a volume defined by the reaction chamber, the present invention precludes the deposition of such parasitically deposited material within the reaction chamber.

The at least one linear plasma source assembly and at least one radiofrequency generator are attached to at least one movable wall and are configured to allow the at least one radiofrequency generator to deliver radio wave radiation to the at least one linear plasma source assembly.

Preferably, the apparatus additionally comprises at least one radio wave waveguide attached to the at least one moveable wall. The radio wave waveguide is configured to allow radio waves to be transmitted from at least one radio wave generator to at least one end of at least one linear antenna. More preferably, the at least one linear plasma source assembly (12), the at least one radiofrequency generator (15) and the at least one radio wave waveguide (17) attached to the at least one moveable wall are configured: (i) to allow the at least one radiofrequency generator (15) to deliver radio wave radiation to a first, proximal end of the linear (radio wave) antenna; and (ii) to allow the at least one radiofrequency generator (15) to deliver radio wave radiation to a second, proximal end of the linear radio wave antenna. This specific configuration advantageously allows for a very compact arrangement of elements. This specific configuration also advantageously allows for the plasma source assembly (12), the at least one radiofrequency generator (15) and the at least one radio wave waveguide (17) to be cleaned without necessitating separation from each other and consequential time- and energy-consuming re-alignment to achieve a stable plasma generation along the linear plasma source assembly. This obviated re-alignment is often necessitated so that radiation is provided to each distal end of the linear antenna at the correct phase to give rise to a stable standing wave, which is typically required to provide uniform plasma generation along the linear plasma source, and hence allows for uniform plasma enhanced chemical vapour deposition along the length of the linear plasma source.

The radio wave waveguide may be comprised of metal, preferably aluminium.

Preferably, the radio wave waveguide is not coaxial with the linear antenna. Preferably, the radio wave waveguide is parallel to and offset from the linear antenna.

In a preferred embodiment, radio frequency generator may be placed in direct contact with the radio wave waveguide.

In an alternative, equally preferred embodiment, the radio frequency generator may transmit radio frequency waves to the radio wave waveguide via a wave-splitter.

Preferably, the apparatus according to the first aspect additionally comprises at least one parasitic deposition shielding element attached to the at least one movable wall.

Preferably, the apparatus according to the first aspect, according to any of the previous embodiments, additionally comprises at least one gas supply means attached to the at least one movable wall, preferably wherein the gas supply mean comprises a plurality of nozzles. This advantageously allows parasitically deposed material to be removed from the gas supply means without accidental deposition of parasitically deposed material within the apparatus.

Preferably, the gas supply conduit(s) comprises a first gas supply means. The first gas supply means preferably comprises a first gas supply conduit and a first plurality of nozzles in fluid communication with the first gas supply conduit. The first gas supply means is configured to allow a first gas to be supplied to the coaxial dielectric tube. This advantageously allows the provision of a first plasma forming gas to the plasma forming region proximal to the coaxial dielectric tube. Preferably, the first plurality of nozzles are at a distance of 10-75 mm from the closest coaxial dielectric tube(s) of the linear microwave source(s), more preferably 20-65 mm, yet more preferably 30-55 mm and most preferably 35-45 mm. An apparatus according to any embodiment of the first invention with a first plurality of gas nozzles at these preferable distances from the coaxial dielectric tube is believed to be advantageously atom and energy efficient in provision of a plasma from a first gas.

More preferably, the gas supply conduit(s) additionally comprises a second gas supply means. The second gas supply means preferably comprises a second gas supply conduit and a second plurality of nozzles in fluid communication with the second gas supply conduit. The second gas supply means is configured to allow a second gas to be supplied. Preferably, the means for providing a second gas wherein the second plurality of nozzles are at a distance of 20-200 mm from the coaxial dielectric tube(s) of the closest linear microwave source(s), more preferably 75-175 mm, yet more preferably 100-150 mm and most preferably 125-135 mm. An apparatus according to any embodiment of the first invention with a second plurality of gas nozzles at these preferable distances from the coaxial dielectric tube are believed to be advantageously atom and energy efficient in homogeneous layer deposition.

In a particularly favoured embodiment, the apparatus comprises both a first supply means and a second gas supply means as described above, wherein the first plurality of nozzles are at a distance of 10-75 mm from the coaxial dielectric tube(s) of the linear microwave source(s) and the second plurality of nozzles are at a distance of 50-200 mm from the coaxial dielectric tube(s) of the linear microwave source(s). More preferably wherein the first plurality of nozzles and the second plurality of nozzles are at a distance of 20-65 mm and 75-175 mm from the coaxial dielectric tube(s) of the closest linear microwave source(s), respectively, even more preferably at a distance of from 30-55 mm and 100-150 mm, respectively, and most preferably at a distance of from 35-45 mm and 125-135 mm, respectively.

Preferably, the apparatus according to the first aspect, according to any of the previous embodiments, additionally comprises at least one gas exhaust conduit attached to the at least one movable wall, preferably wherein the at least one gas exhaust conduit comprise a plurality of nozzles. This advantageously allows parasitically deposed material to be removed from the gas exhaust conduit(s) without accidental deposition of parasitically deposed material within the apparatus.

Preferably, the apparatus according to the first aspect, according to any of the previous embodiments, additionally comprises at least one internal frame element reversibly attached to the at least one movable wall, wherein the at least one linear plasma source assembly is attached to the at least one movable wall by means of the at least one internal frame element. This advantageously allows rapid detachment of the frame element and the at least one linear plasma source assembly without direct manipulation of the typically fragile coaxial dielectric tube(s), minimizing accidental breakage and minimizing accidental deposition of parasitically deposed material within the reaction chamber.

The apparatus according to the first aspect, according to any of the previous embodiments, is preferably configured such that:
the at least one radio wave waveguide is attached to the at least one moveable wall by means of the at least one internal frame element; and/or
the at least one gas supply conduit is attached to the at least one moveable wall by means of the at least one internal frame element; and/or
the at least one gas exhaust conduit is attached to the at least one moveable wall by means of the at least one internal frame element.

This advantageously allows rapid detachment of the frame element and the: (i) radio wave waveguide, (ii) gas supply conduit(s) and/or (iii) gas exhaust conduit(s) without direct manipulation of the typically delicate (i) radio wave waveguide, (ii) gas supply conduit(s) and/or (iii) gas exhaust conduit(s), minimizing accidental distortion/bending/rupturing of the waveguide and/or conduits and minimizing accidental deposition of parasitically deposed material within the reaction chamber.

The apparatus according to the first aspect, according to any of the previous embodiments, wherein the linear antenna is a microwave antenna, the one or more radiofrequency generators microwave generators, the radio wave guide is a microwave guide and the radio wave radiation is microwave radiation.

The apparatus according to the first aspect, according to any of the previous embodiments, wherein the ratio of radio wave generators to linear plasma source is 1:1 or 2:1, preferably 1:1.

Preferably, the linear plasma assembly comprises only one radio wave generator per linear antenna.

Preferably, the apparatus according to any of the previous embodiments of the first aspect, is one wherein the ratio of waveguides to linear plasma source is 1:1 or 1:2, preferably 1:1.

Preferably, the apparatus according to any of the previous embodiments of the first aspect, is one wherein a first radio wave generator is configured to allow radio wave radiation to be delivered to a first, proximal end of the linear (radio wave) antenna and wherein a second radio wave generator is configured to allow radio wave radiation to be delivered to a second, distal end of the linear (radio wave) antenna via the radio wave waveguide.

Preferably, the apparatus additionally comprises baffles consisting of dielectric lamella. These baffles are configured so as to direct plasma and gas flows in one or more directions, and thereby advantageously reduce parasitic deposition. Most preferably, the baffles are configured to direct flow of a first gas and a second gas from the first gas supply means and the second gas supply means, respectively, to the linear plasma source(s) and then direct waste gas towards the gas exhaust conduit(s).

Preferably, the apparatus according to any embodiment of the first aspect is one in which comprises arrays of linear plasma sources, wherein each linear plasma source comprises a coaxial plasma linear source. This configuration may advantageously: (i) allow for more energy efficient PECVD; and (ii) allow the apparatus to deposit substantially uniform coatings of ultra large area (greater than 1 m²) at high deposition rate to form dense and thick films (e.g. 5-10 μm thick).

According to a second aspect, the present invention concerns a method for deposition coating onto a substrate using an apparatus according to any embodiment of the first aspect. Preferably, the method is one in which the method is for deposition coating onto a microwave absorbing substrate. More preferably, the method is one in which the method is for deposition coating onto a metallic foil.

Preferably, the method comprises the following steps:
provision of a substrate to an apparatus according to any embodiment according to the first aspect;
provision of electrical energy to the radio wave generator to generate radio waves;
provision of radio wave radiation from the radio wave generator to a first distal end of the linear antenna of the plasma source assembly;
   provision of radio wave radiation from the radio wave generator to a second distal end of the linear antenna of the plasma source assembly, optionally via a radio wave waveguide;
   provision of a first gas capable of forming a plasma to the coaxial dielectric tube to allow plasma formation at the coaxial dielectric tube;
   provision of a second gas to the reaction chamber;
   allowing deposition of a coating onto the substrate.

Preferably, the first gas comprises a chemically inert carrier gas, preferably wherein the inert carrier gas is selected from nitrogen, helium, argon or combination thereof, more preferably the inert carrier gas is selected from nitrogen helium, argon, or a combination of these gasses, most preferably the inert carrier gas is argon.

Preferably, the first gas comprises a reactive gas, preferably the reactive is selected from hydrogen, oxygen ammonia, nitrous oxide, methane, acetylene, ethane, ethene, propane, propene or any combination of these gasses, more preferably hydrogen.

Preferably, the second gas comprises a precursor gas, more preferably the precursor gas is selected from SiH₄, SiH₃Cl, SiH₂Cl₂, SiHCl₃, SiCl₄, Si₂H₆, Si₂Cl₆, Si₃H₈, SiEt₂H₂ or cyclohexasilane.

More preferably, first gas consists of a chemically inert carrier gas and a reactive gas and the second gas is a precursor gas, most preferably the chemically inert carrier gas is argon, the reactive gas is hydrogen and the precursor gas is SiH₄.

Preferably, the method is one in which the linear (radio wave) antenna is a microwave antenna, the radiofrequency generator is a microwave generator, the radio wave guide is a microwave guide and the radio wave radiation is microwave radiation.

According to a third aspect, the present invention concerns a method for cleaning an apparatus according to any embodiment according to the first aspect, comprising the steps of:
Ensuring the pressure within the reaction chamber is approximately equal to the pressure outside the reaction chamber;
Moving the movable wall from the first operational position to the second non-operational position;
Cleaning parasitically deposed material from at least one linear plasma source assembly;
Optionally cleaning parasitically deposed material from: (i) the radio wave waveguide(s), (ii) the parasitic deposition shielding element(s), (iii) the gas supply conduit(s), (iv) the gas exhaust conduit(s) and/or (v) the internal frame element(s), where these elements are both present and attached to the moveable wall; and
Moving the movable wall from the second non-operational position to the first operational position.

Preferably, the method additionally comprises the following steps:
detaching the at least one linear plasma source from the apparatus before cleaning parasitically deposed material from at least one linear plasma source assembly; and
reattaching the at least one linear plasma source to the apparatus after cleaning parasitically deposed material from at least one linear plasma source assembly.

The step of detaching the at least one linear plasma source from the apparatus is performed after the step of moving the movable wall from the first operational position to the second non-operational position. The step of reattaching the at least one linear plasma source to the apparatus is performed before the step of moving the movable wall from the second non-operational position to the first operational position.

Even more preferably, the method additionally comprises the following steps:
detaching the at least one linear plasma source from the apparatus before cleaning parasitically deposed material from at least one linear plasma source assembly; detaching the (i) the radio wave waveguide(s), (ii) the parasitic deposition shielding element(s), (iii) the gas supply conduit(s), (iv) the gas exhaust conduit(s) and/or (v) the internal frame element(s) where these elements are both present and attached to the moveable wall before cleaning parasitically deposed material from the (i) the radio wave waveguide(s), (ii) the parasitic deposition shielding element(s), (iii) the gas supply conduit(s), (iv) the gas exhaust conduit(s) and/or (v) the internal frame element(s)
reattaching the at least one linear plasma source to the apparatus after cleaning parasitically deposed material from at least one linear plasma source assembly; and
reattaching the (i) the radio wave waveguide(s), (ii) the parasitic deposition shielding element(s), (iii) the gas supply conduit(s), (iv) the gas exhaust conduit(s) and/or (v) the internal frame element(s) after cleaning parasitically deposed material from the (i) the radio wave waveguide(s), (ii) the parasitic deposition shielding element(s), (iii) the gas supply conduit(s), (iv) the gas exhaust conduit(s) and/or (v) the internal frame element(s).

The detaching steps are performed after the step of moving the movable wall from the first operational position to the second non-operational position. The reattachment steps are performed before the step of moving the movable wall from the second non-operational position to the first operational position.

Most more preferably, the method additionally comprises the following steps:
detaching the at least one linear plasma source from the apparatus before cleaning parasitically deposed material from at least one linear plasma source assembly;
detaching the (i) the radio wave waveguide(s), (ii) the parasitic deposition shielding element(s), (iii) the gas supply conduit(s), (iv) the gas exhaust conduit(s) and (v) the internal frame element(s) before cleaning parasitically deposed material from the (i) the radio wave waveguide(s), (ii) the parasitic deposition shielding element(s), (iii) the gas supply conduit(s), (iv) the gas exhaust conduit(s) and (v) the internal frame element(s)
reattaching the at least one linear plasma source to the apparatus after cleaning parasitically deposed material from at least one linear plasma source assembly; and
reattaching the (i) the radio wave waveguide(s), (ii) the parasitic deposition shielding element(s), (iii) the gas supply conduit(s), (iv) the gas exhaust conduit(s) and/or (v) the internal frame element(s) after cleaning parasitically deposed material from the (i) the radio wave waveguide(s), (ii) the parasitic deposition shielding element(s), (iii) the gas supply conduit(s), (iv) the gas exhaust conduit(s) and (v) the internal frame element(s).

The detaching steps are performed after the step of moving the movable wall from the first operational position to the second non-operational position. The reattachment steps are performed before the step of moving the movable wall from the second non-operational position to the first operational position.

According to a fourth aspect, the invention related to the use of an apparatus according to any embodiment of the first aspect of the invention.

Within the context of the invention, preferably the linear plasma assembly comprises only one radio wave generator per linear antenna.

In the context of the invention the PECVD process may be a low-pressure PECVD process. For example, in an embodiment the low-pressure PECVD process comprises pressures above 0.15 mbar, so that a sustainable plasma can be maintained when a mixture of the silicon compound gas e.g. silane, SiH₄, and hydrogen, H₂, is used. In another embodiment the low-pressure PECVD process comprises pressures below 0.15 mbar when the mixture of e.g., silane, SiH₄, and hydrogen, H₂, further comprises argon (Ar).

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

### DESCRIPTION OF THE EMBODIMENTS

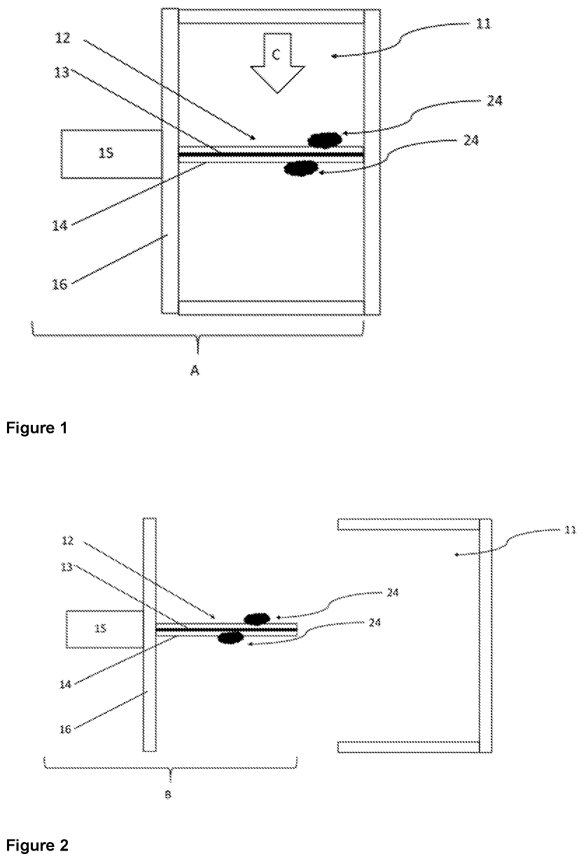

FIG. 1 depicts a top-down cross-sectional view of an apparatus according to the first aspect of the invention with the moveable wall in a first operational position. FIG. 1 depicts an apparatus (10) suitable for plasma enhanced chemical vapour deposition. It comprises a reaction chamber (11) and a linear plasma source assembly (12). The linear plasma source assembly (12) comprises (i) a linear antenna (13) and (ii) a coaxial dielectric tube (14) around the linear (radio wave) antenna (13). By way of non-limiting example, a suitable linear plasma source assembly may comprise a copper linear antenna (113) and a quartz dielectric tube (114). The apparatus additionally comprises a radiofrequency generator (15). By way of non-limiting example, the radiofrequency generator (15) may be a magnetron capable of emitting microwave energy at 2.5 GHZ and approximately 6 KW of c/w power output. The reaction chamber (11) is configured with at least one movable wall (16). The movable wall (16) is depicted here in the first operational position (A). Optionally, the moveable wall (16) and the reaction chamber (11) may form a gas-tight seal, allowing the reaction chamber to be evacuated to low pressures (such as 100 Pa).

The apparatus depicted in FIG. 1 suitable for plasma enhanced chemical vapour deposition. A method that may be employed is as follows. First a substrate is provided to the apparatus (substrate not depicted). By way of no-limiting example, the substrate may be provided as a continuous copper foil (not depicted) from a drum (not depicted), via rollers (not depicted) and into the reaction chamber through ports (not depicted) such that the substrate passes past the linear plasma source. Electricity is provided to the radio wave generator (15), which then generates radio waves. By way of non-limiting example. Such a radio wave generator (15) may optionally be a magnetron that then emits microwave energy at 2.45 GHZ and approximately 6 KW of c/w power output. The generated radio wave radiation from the radio wave generator (15) is provided to the linear (radio wave) antenna (13) of the plasma source assembly (12). Optionally, the radiation is provided to only one distal end of the linear (radio wave) antenna (13). Preferably, the radiation is provided to a first distal end and to a second distal end of the linear (radio wave) antenna (13). This may be optionally achieved using two radio wave generators, one attached to the movable wall (16) and the other (not depicted) attached to an opposite wall of the reaction chamber (11). Alternatively, this may be optionally achieved by means of a radio wave waveguide (17, not depicted). Then a first gas capable of forming a plasma is provided to the coaxial dielectric tube (14) via a first gas supply means (19A, not depicted) to allow plasma formation at the coaxial dielectric tube (14). This generates a plasma generally symmetric along the length of the linear plasma source (12). A second gas is provided to the reaction chamber by a second gas supply means (19B, not depicted). The method then allows deposition of a coating onto the substrate.

During deposition, material is expected to depose parasitically onto various internal components of the apparatus (depicted here in cartoon fashion, 24). Deposition onto the coaxial dielectric tube (14) is expected to occur most rapidly, with deposition onto the gas supply means (19A, 19B) expected to occur less rapidly. After an extended period of continuous deposition, or alternatively several batch deposition runs, the accumulated parasitically deposed material is expected to start to detach from the components where it has accumulated (often referred to as “flaking off”). This would lead to deleterious effects on the coated material, due primarily to heterogeneous coating of the substrate.

To avoid this deleterious effect, the apparatus according to the present invention may be opened by moving the movable wall to a second, non-operational position. This is depicted in FIG. 2. When the movable wall (16) or wall section is in the second non-operational position, it is not possible to depose material onto a substrate. By way of a non-limiting example, moving the wall to this second position may be accomplished using rolling means or rails, which advantageously reduce or entirely avoid detachment of parasitically deposed material during moving the door by minimizing vibration or shocks during movement of the wall or wall section. Advantageously, the parasitically deposed material can be removed without risking accidental deposition of material within the reaction chamber. By way of a non-limiting example, the parasitically accumulated material may be removed by physical abrasion without risking flakes falling onto or into the reaction chamber or the rolling means. This speeds up maintenance and improved the quality of obtainable coated substrates. By way of a non-limiting example, parasitically accumulated material may also, or alternatively, be removed by physically replacing the parasitically coated coaxial dielectric tubes (14A) with clean coaxial dielectric tubes (14B). This may be done much more rapidly than cleaning the parasitically coated coaxial dielectric tubes (14A) in situ, and allows the first set of parasitically coated coaxial dielectric tubes (14A) to be cleaned whilst the apparatus is operating with a second set of coaxial dielectric tubes (14B). This generally results in overall higher manufacturing efficiencies and higher quality coated substrates; and also allows maintenance work on removed wall or wall sections, while also giving easier access to those parts that remain in the operational position.

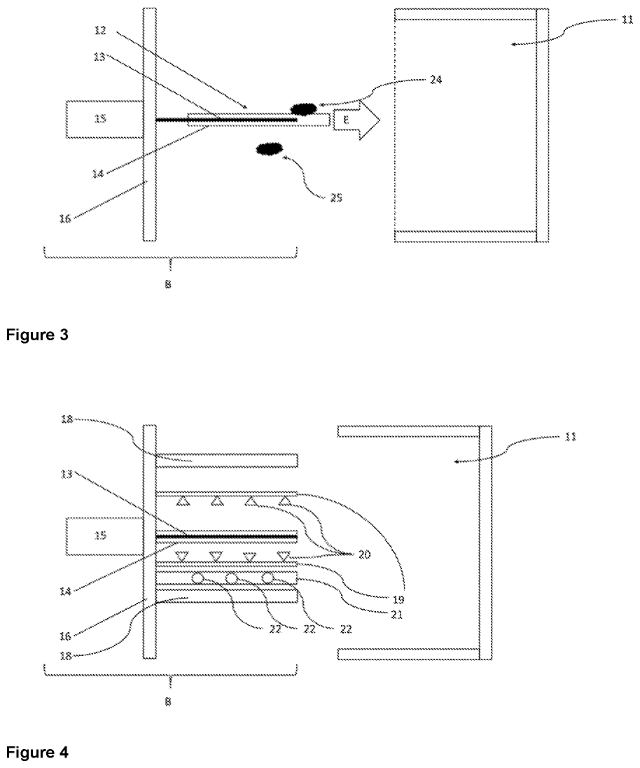

FIG. 3 depicts a top-down cross-sectional view of the same apparatus as depicted in FIGS. 1 and 2, depicting accidental detachment of parasitically deposited material on detachment of coaxial dielectric tube (14), which does not result in accidental deposition of the of parasitically deposited material within the reaction chamber.

FIG. 4 depicts a top-down cross-sectional view of an embodiment of the apparatus according to the first aspect of the invention, with parasitic deposition shielding elements (18), gas supply means (19) and gas exhaust means (21). The moveable wall is in a second non-operational position.

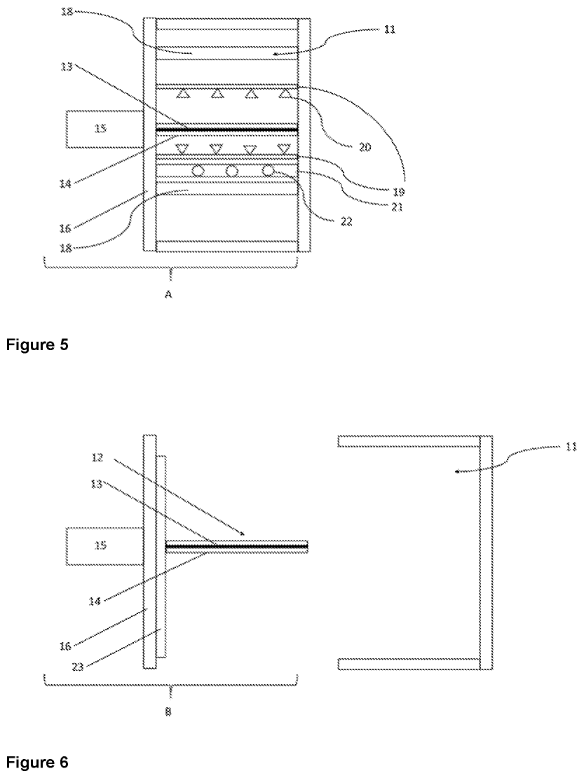

FIG. 5 depicts a top-down cross-sectional view of the same embodiment of the apparatus as depicted in FIG. 4. The moveable wall is in a first operational position.

FIG. 6 depicts a top-down cross-sectional view of an apparatus according to an embodiment of the first aspect of the invention comprising internal frame element (23). The moveable wall (16) is in a first operational position.

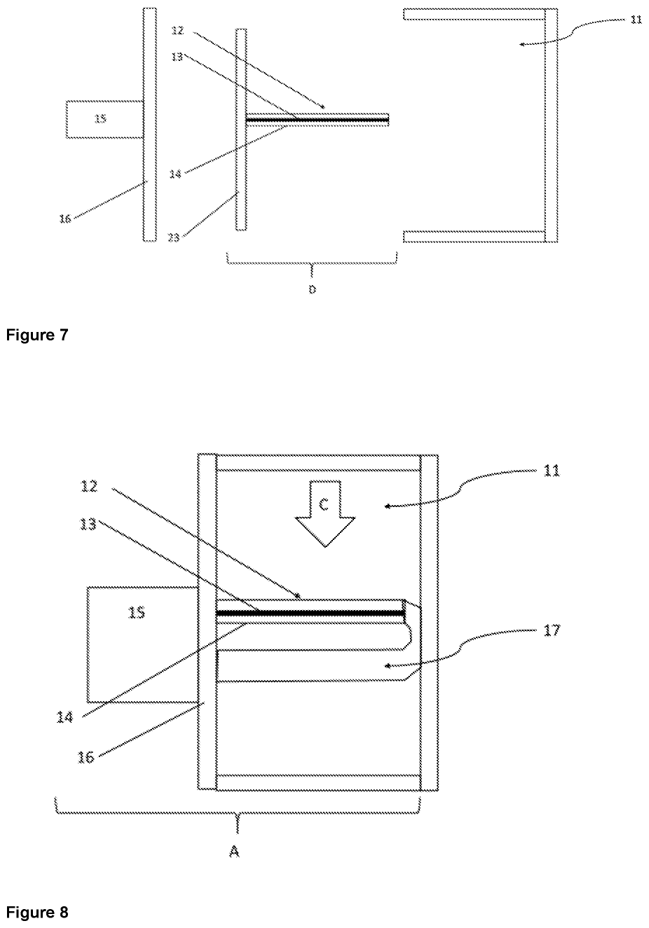

FIG. 7 depicts a top-down cross-sectional view of the same apparatus as depicted in FIG. 6. moveable wall (16) is in a second non-operational position. The internal frame element (23) has been reversibly detached from the moveable wall (16). The detachment of the internal frame element allows for rapid detachment of elements attached to the internal frame element.

FIG. 8 depicts a top-down cross-sectional view of an apparatus according to an embodiment of the first aspect of the invention, comprising a radio wave waveguide (17).

In a typical continuous PECVD deposition process of silicon onto a copper substrate using silane (SiH₄), it is anticipated that the coaxial dielectric tube(s) (14) will need to be cleaned of parasitic deposition after 100 hours of continuous operation. Where present, it is expected that the parasitic deposition shielding element(s) (18) will need to be cleaned of parasitic deposition every 100 hours (after which it is anticipated that a parasitic layer of approximately 3 mm. It is anticipated that the gas supply means (19) and gas exhaust means (21) will only need to be cleaned after 1,000-2,000 hours of continuous operation. The present invention therefore allows the apparatus to be quickly maintained.

In a preferred embodiment, two or more magnetron sources are based on moveable wall section or wall, whereby art least one is configured to feeding to the antenna, while the second may advantageously be configured to feed to the waveguide.

In a further alternative preferred embodiment, two antennas are positioned on the removable wall or wall section, with one magnetron source with a splitter, or two magnetron sources, and a waveguide positioned between these antennas. These preferred embodiments may have the benefit of being able to create an essentially linear homogeneous plasma with microwave feed from one side only which may be advantageously be removed for maintenance and cleaning.

### LIST OF REFERENCES

Similar reference numbers used in the description to indicate similar elements (but only differ in the hundreds) are implicitly included [e.g. 101 and 201].
10 apparatus suitable for plasma enhanced chemical vapour deposition.
11 reaction chamber.
12 linear plasma source assembly.
13 linear antenna.
14 coaxial dielectric tube.
15 radiofrequency generator.
16 movable wall.
17 radio wave waveguide.
18 parasitic deposition shielding element.
19 gas supply means.
20 nozzles.
21 gas exhaust.
22 nozzles.
23 internal frame element.
24 parasitically deposited material.
25 accidentally detached parasitically deposited material.
A first operational location.
B second non-operational location.
C direction of substrate movement when deposition in progress.
D internal frame element (23) and linear plasma source assembly (12), reversibly detached from movable wall (16).
E direction of detachment of coaxial dielectric tube.

1-17. (canceled)

18. An apparatus for plasma enhanced chemical vapour deposition, comprising:
a) a reaction chamber;
b) at least one linear plasma source assembly comprising (i) at least one linear antenna and (ii) at least one coaxial dielectric tube positioned around the linear antenna; and
c) at least one radiofrequency generator;
wherein the reaction chamber is configured with at least one movable wall, the wall being configured to be movable between a first operational location (A) and a second non-operational location (B); and
the at least one linear plasma source assembly and at least one radiofrequency generator are attached to at least one movable wall and are configured to allow the at least one radiofrequency generator to deliver radio wave radiation to the at least one linear plasma source assembly.

19. The apparatus according to claim 18, wherein the apparatus additionally comprises at least one radio wave waveguide attached to the at least one moveable wall.

20. The apparatus according to claim 18, wherein the apparatus additionally comprises at least one parasitic deposition shielding element attached to the at least one movable wall.

21. The apparatus according to claim 18, wherein the apparatus additionally comprises at least one gas supply means attached to the at least one movable wall, preferably wherein the gas supply means comprises a plurality of nozzles.

22. The apparatus according to claim 18, wherein the apparatus additionally comprises at least one gas exhaust conduit attached to the at least one movable wall, preferably wherein the at least one gas exhaust conduit comprise a plurality of nozzles.

23. The apparatus according to claim 18, wherein the apparatus additionally comprises at least one internal frame element reversibly attached to the at least one movable wall, wherein:
the at least one linear plasma source assembly is attached to the at least one movable wall by means of the at least one internal frame element.

24. The apparatus according to claim 23, wherein:
the at least one radio wave waveguide is attached to the at least one moveable wall by means of the at least one internal frame element; and/or
the at least one gas supply conduit is attached to the at least one moveable wall by means of the at least one internal frame element; and/or
the at least one gas exhaust conduit is attached to the at least one moveable wall by means of the at least one internal frame element.

25. The apparatus according to claim 18, wherein the antenna is a microwave antenna, the one or more radiofrequency generators microwave generators, the radio wave guide is a microwave guide, and the radio wave radiation is microwave radiation.

26. The apparatus according to claim 18, wherein the ratio of radio wave generators to linear plasma source is 1:1 or 2:1, preferably 1:1.

27. The apparatus according to claim 18, wherein the ratio of waveguides to linear plasma source is 1:1 or 1:2, preferably 1:1.

28. The apparatus according to claim 18, wherein a first radio wave generator is configured to allow radio wave radiation to be delivered to a first, proximal end of the linear radio wave antenna and wherein a second radio wave generator is configured to allow radio wave radiation to be delivered to a second, distal end of the linear antenna via the radio wave waveguide.

29. The apparatus according to claim 19, wherein the at least one linear plasma source assembly, the at least one radiofrequency generator and the at least one radio wave waveguide attached to the at least one moveable wall are configured: (i) to allow the at least one radiofrequency generator to deliver radio wave radiation to a first, proximal end of the linear radio wave antenna; and (ii) to allow the at least one radiofrequency generator to deliver radio wave radiation to a second, proximal end of the linear radio wave antenna.

30. A method for deposition coating onto a substrate using an apparatus according to claim 18.

31. The method of claim 30, wherein the method is for deposition coating onto a microwave absorbing substrate, preferably a metallic substrate.

32. A method for cleaning an apparatus according to claim 18, comprising the steps of:
ensuring the pressure within the reaction chamber is approximately equal to the pressure outside the reaction chamber;
moving the movable wall from the first operational position to the second non-operational position;
cleaning parasitically deposed material from at least one linear plasma source assembly;
optionally cleaning parasitically deposed material from: (i) the radio wave waveguide(s), (ii) the parasitic deposition shielding element(s), (iii) the gas supply conduit(s), (iv) the gas exhaust conduit(s) (and/or v) the internal frame element(s), where these elements are both present and attached to the moveable wall; and
moving the movable wall from the second non-operational position to the first operational position.

33. The method according to claim 32, comprising the additional steps of:
detaching the at least one linear plasma source from the apparatus before cleaning parasitically deposed material from at least one linear plasma source assembly; and
reattaching the at least one linear plasma source to the apparatus after cleaning parasitically deposed material from at least one linear plasma source assembly.
